(19) United States
(12) Patent Application Publication
(10) Pub. No.: US 2019/0184957 A1
(43) Pub. Date: Jun. 20, 2019

(54) FAULT DIAGNOSIS FOR FAULT TOLERANT CHASSIS ARCHITECTURE SYSTEMS

(71) Applicant: GM Global Technology Operations LLC, Detroit, MI (US)

(72) Inventors: Yixin Yao, Ann Arbor, MI (US); Lance A. Smith, Farmington Hills, MI (US); Leibing Yu, Novi, MI (US)

(21) Appl. No.: 15/843,411

(22) Filed: Dec. 15, 2017

(51) Int. Cl. B60T 17/22; G01R 31/28; G07C 5/08

(52) U.S. Cl. CPC B60T 17/221; G01R 31/2829; B60T 2270/404; B60T 2270/82; B60T 2270/406; G07C 5/0808

(57) ABSTRACT

Examples of techniques for fault diagnosis for fault tolerant chassis architecture systems are disclosed. In one example implementation according to aspects of the present disclosure, a computer-implemented method includes receiving, by a processing device, a control variable for the system. The method further includes receiving, by the processing device, a measured variable for the system. The method further includes calculating, by the processing device, a residual based at least in part on the control variable and the measured variable. The method further includes performing, by the processing device, a fault diagnosis to detect a fault in the system based at least in part on the residual.

### INTRODUCTION

The present disclosure relates generally to brake-by-wire systems and more particularly to fault diagnosis for fault tolerant chassis architecture systems.

A vehicle, such as a car, a motorcycle, or any other type of automobile may be equipped with a steer-by-wire (SbW) system and/or a brake-by-wire (BbW) system. Also referred to as drive-by-wire systems, SbW and BbW systems use electrical and/or electro-mechanical systems to control the vehicle (e.g., steering, braking) instead of traditional mechanical linkages. For example, a steer-by-wire system and/or a brake-by-wire system uses electromechanical actuators and human-machine interfaces (e.g., a steering feel emulator, pedal emulator, etc.) to control the vehicle. Accordingly, mechanical components such as the steering intermediate shaft and other associated components are not needed to control the vehicle.

### SUMMARY

In one exemplary embodiment, a computer-implemented method for fault diagnosis of a system is provided. The method includes receiving, by a processing device, a control variable for the system. The method further includes receiving, by the processing device, a measured variable for the system. The method further includes calculating, by the processing device, a residual based at least in part on the control variable and the measured variable. The method further includes performing, by the processing device, a fault diagnosis to detect a fault in the system based at least in part on the residual.

In some examples, performing the fault diagnosis includes determining whether the residual exceeds a threshold. In some examples, the fault diagnosis indicates that a fault exists in the system when the residual exceeds the threshold. In some examples, the fault diagnosis indicates that a fault does not exist in the system when the residual does not exceed the threshold. In some examples, the measured variable is based at least in part on measuring an output of the system. In some examples, the control variable is based at least in part on estimating an output of the system based at least in part on an input into the system. In some examples, calculating the residual includes subtracting the control variable from the measured variable. In some examples, the fault is in an actuator in the system. In some examples, the fault is in a sensor in the system.

In another exemplary embodiment, a fault diagnosis system is provided. The fault diagnosis system includes a memory comprising computer readable instructions, and a processing device for executing the computer readable instructions for performing a method for fault diagnosis of a system. The method includes receiving, by the processing device, a control variable for the system. The method further includes receiving, by the processing device, a measured variable for the system. The method further includes calculating, by the processing device, a residual based at least in part on the control variable and the measured variable. The method further includes performing, by the processing device, a fault diagnosis to detect a fault in the system based at least in part on the residual.

In some examples, performing the fault diagnosis includes determining whether the residual exceeds a threshold. In some examples, the fault diagnosis indicates that a fault exists in the system when the residual exceeds the threshold. In some examples, the fault diagnosis indicates that a fault does not exist in the system when the residual does not exceed the threshold. In some examples, the measured variable is based at least in part on measuring an output of the system. In some examples, the control variable is based at least in part on estimating an output of the system based at least in part on an input into the system. In some examples, calculating the residual includes subtracting the control variable from the measured variable. In some examples, the fault is in an actuator in the system. In some examples, the fault is in a sensor in the system.

In yet another exemplary embodiment, a computer program product is provided which includes a computer readable storage medium having program instructions embodied therewith, the program instructions executable by a processing device to cause the processing device to perform a method for fault diagnosis of a system. The method includes receiving, by the processing device, a control variable for the system. The method further includes receiving, by the processing device, a measured variable for the system. The method further includes calculating, by the processing device, a residual based at least in part on the control variable and the measured variable. The method further includes performing, by the processing device, a fault diagnosis to detect a fault in the system based at least in part on the residual.

In some examples, performing the fault diagnosis includes determining whether the residual exceeds a threshold.

The above features and advantages, and other features and advantages, of the disclosure are readily apparent from the following detailed description when taken in connection with the accompanying drawings.

### BRIEF DESCRIPTION OF THE DRAWINGS

Other features, advantages, and details appear, by way of example only, in the following detailed description, the detailed description referring to the drawings in which:

FIG. 1 depicts a block diagram of a fault diagnosis system, according to aspects of the present disclosure;

FIG. 2 depicts a block diagram of a fault diagnosis system; according to aspects of the present disclosure;

FIG. 3 depicts a flow diagram of a method for fault diagnosis, according to aspects of the present disclosure;

FIG. 4 depicts a flow diagram of a method for fault diagnosis, according to aspects of the present disclosure;

FIG. 5 depicts a block diagram of a fault detection implementation using a fault diagnosis system to detect a fault within a system, according to aspects of the present disclosure;

FIG. 6A depicts a graph of an aspect of the fault detection implementation of FIG. 5, according to aspects of the present disclosure;

FIG. 6B depicts a graph of another aspect of the fault detection implementation of FIG. 5, according to aspects of the present disclosure;

FIG. 6C depicts a graph of another aspect of the fault detection implementation of FIG. 5, according to aspects of the present disclosure; and

FIG. 7 depicts a block diagram of a processing system for implementing the techniques described herein, according to aspects of the present disclosure.

### DETAILED DESCRIPTION

The following description is merely exemplary in nature and is not intended to limit the present disclosure, its application or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

The technical solutions described herein provide for fault diagnosis for fault tolerant chassis architecture (FTCA) systems, such as a brake-by-wire (BbW) system. In particular, the present disclosure describes a real-time fault diagnosis system and method for vehicle FTCA BbW systems. This is accomplished by using model-based analytical redundancy instead of traditional hardware redundancy. The fault detection techniques described herein can be applied more generally to sensors, actuators, and other system components as well as FTCA systems as a whole while establishing a low-cost advantage over traditional hardware redundant implementations.

Traditional fault diagnosis systems that use hardware redundancy are inefficient in terms of cost, space, and installation. For example, these traditional hardware redundant systems require hardware redundancy, and the additional hardware occupies additional physical space, costs more, requires additional labor for installation and maintenance, and the like. To address these problems, the present techniques use model-based redundancy based on analytical redundancy. The analytical redundancy techniques of the present disclosure use a controlled FTCA system mathematical model based on control technology to implement a consistency check between control variables and measured variables. The results are residual signals, which represent the difference between the control variables and the measured variables. Faults are detected from the residual signals, for example, in cases where a residual signal exceeds a given threshold. The described model-based approach is high performance and robust with respect to model uncertainty and sensitive to faults. Fault isolation can also be realized by using a model of the physical FTCA system to determine which component of the FTCA system is at fault.

The technical solutions described herein provide a number of benefits. For example, the present fault diagnosis techniques use less hardware than existing approaches that require hardware redundancy. This, accordingly, improves fault diagnosis systems by reducing hardware complexity, reducing costs, improving reliability, robustness, and performance.

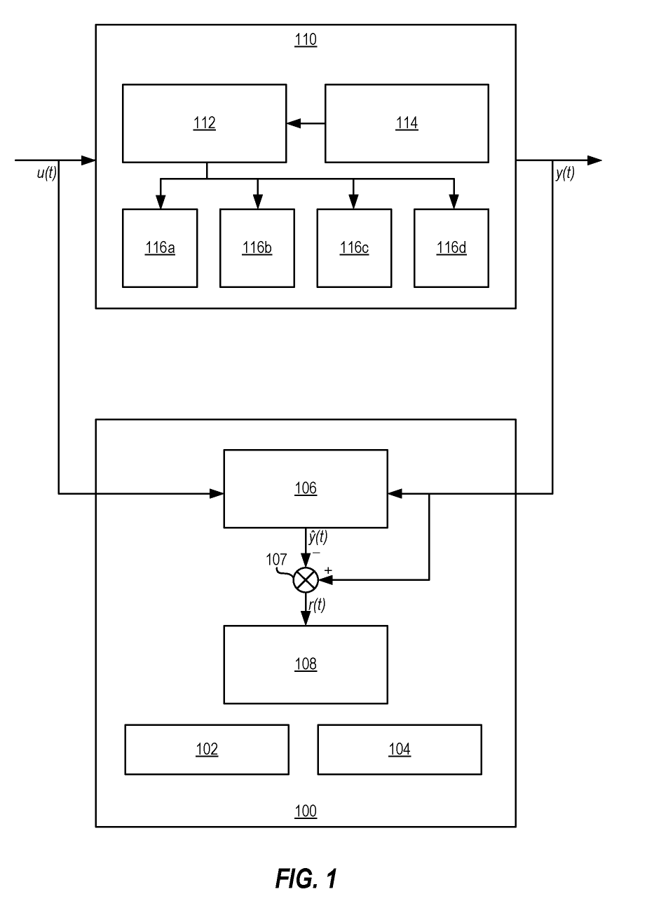

FIG. 1 depicts a block diagram of a fault diagnosis system 100, according to aspects of the present disclosure. The various components, modules, engines, etc. described regarding FIG. 1 can be implemented as instructions stored on a computer-readable storage medium, as hardware modules, as special-purpose hardware (e.g., application specific hardware, application specific integrated circuits (ASICs), as embedded controllers, hardwired circuitry, etc.), or as some combination or combinations of these.

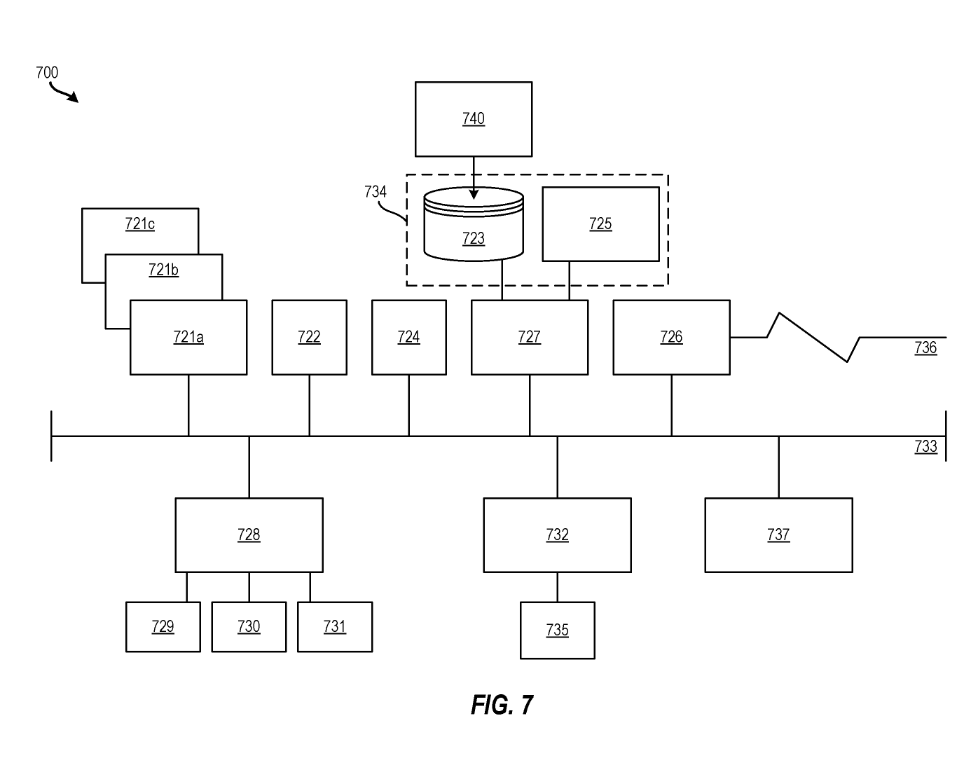

In examples, the module(s), component(s), controller(s), engine(s), etc. described herein can be a combination of hardware and programming. The programming can be processor executable instructions stored on a tangible memory, and the hardware can include the processing device (e.g., the processor 721 of FIG. 7) for executing those instructions. Thus a system memory (e.g., random access memory 724 of FIG. 7) can store program instructions that when executed by the processing device implement the engines described herein. Other engines, components, modules, controllers, etc. can also be utilized to include other features and functionality described in other examples herein.

The fault diagnosis system 100 monitors the input vector (control variables) and output vector (measured variables) of an FTCA system 110 to determine whether a fault exists within the FTCA system 110. In the example of FIG. 1, the FTCA system 110 includes a controller 112 that receives signals from an emulator 114 (e.g., a brake pedal emulator in a BbW system) and sends appropriate commands to the actuators 116a, 116b, 116c, 116d based on the signal received from the emulator 114. The actuators 116a-116d can be, for example, brake actuators in a BbW system, where each actuator is associated with a wheel of a vehicle (e.g., the actuator 116a is associated with a front left brake, the actuator 116b is associated with a front right brake, etc.).

The fault diagnosis system 100 includes the processing device 102, the memory 104, a model observer engine 106, and a fault diagnosis engine 108. The model observer engine 106 calculates a residual using a control variable and a measured variable. To do this, the model observer engine 106 generates an estimated system output of the FTCA system 110 using the control variable (i.e., an input to the FTCA system 110) and the measured variable (i.e., an output of the FTCA system 110) and uses the estimated system output to calculate the residual. According to the example of FIG. 1, the estimated system output of the FTCA system 110 is designated ŷ(t). The model observer engine 106 uses the estimated system output (e.g., ŷ(t)) to calculate the residual signal (shown at block 107), designated r(t). The residual signal r(t) is equal to the sum of the measured variable and a fault component f(t) (caused by a fault in the FTCA system 110) minus the estimated system output. That is, r(t)=(y(t)+f(t))−ŷ(t). The residual r(t) is fed into the fault diagnosis engine 108.

The fault diagnosis engine 108 uses the residual to perform a fault diagnosis to determine whether a fault exists within the FTCA system 110. In an example, detecting a fault includes comparing the residual to a threshold. The threshold can be set based on acceptable operating limits, known fault levels, and/or other factors. If the threshold is exceeded, a fault is determined to exist. In another example, detecting a fault includes time averaging the residual and comparing the time average to a threshold. If the threshold is exceeded, a fault is determined to exist). By time averaging the residual, temporary spikes, that in some cases may not indicate a fault, are eliminated. For example, a fault is determined to exist when the residual exceeds the threshold for a period of time. When a fault is determined to exist, the fault diagnosis engine 108 generates a fault message indicating the fault. The fault message can include information about a component (e.g., sensor, actuator, etc.) that is at fault, when the fault occurred, data about the fault detection, and the like.

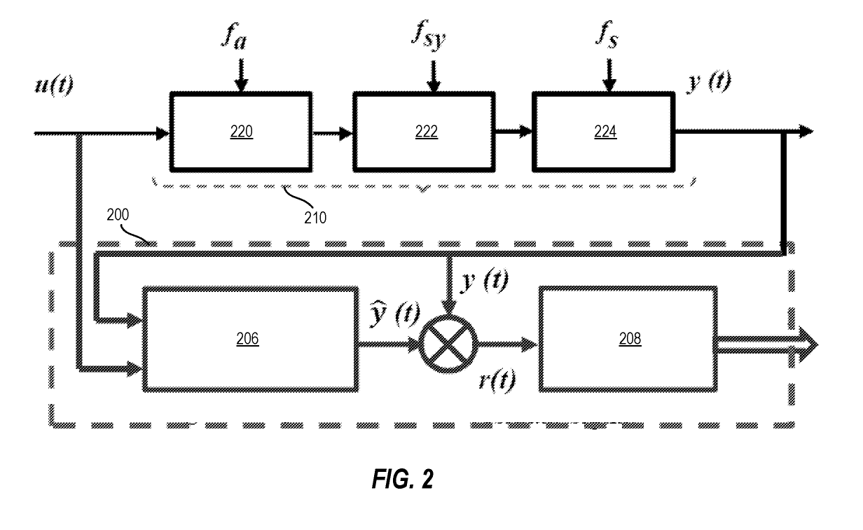

FIG. 2 depicts a block diagram of fault diagnosis system 200, according to aspects of the present disclosure. The various components, modules, engines, etc. described regarding FIG. 2 can be implemented as instructions stored on a computer-readable storage medium, as hardware modules, as special-purpose hardware (e.g., application specific hardware, application specific integrated circuits (ASICs), as embedded controllers, hardwired circuitry, etc.), or as some combination or combinations of these.

According to aspects of the present disclosure, the present techniques apply real-time model-based analytical redundancy to provide fault diagnosis for sensors, actuators, and other system components based on the model. Accordingly, the fault diagnosis system 200 is high performance and robust with respect to model uncertainty and sensitive to faults. The fault diagnosis system 200 can also implement fault isolation by using models of the physical system 210 to determine which component is experiencing a fault (e.g., the actuators 220, the system components 222, and/or the sensors 224).

According to aspects of the present disclosure, the fault diagnosis system 200 detects faults in the system 210, which can include actuators 220, system components 222, and sensors 224. A model observer engine 206 receives the control variable (e.g., the input u(t)) and the measured variable (e.g., the output y(t)). The model observer engine 206 generates an estimated system output (e.g., ŷ(t) of the system 210 and calculates a residual r(t).

The fault diagnosis engine performs a fault diagnosis to detect a fault in the system 210 based on the residual r(t) as described herein. The fault is detected for each of the actuators 220, the system components 222, and the sensors 224. Each of the actuators 220, the system components 222, and the sensors 224 includes a fault component (e.g., fₐ for the actuators 220, f_{sy} for the system components 222, and fₛ for the sensors 224).

According to aspects of the present disclosure, the residual r(t) can be expressed as r(t)=r(d, Δ, f) where r(t) is the function of external noise d, the uncertainty Λ of the system 220, and a class of faults f. Wth this residual, the fault diagnosis engine 208 determines whether a fault exists using a threshold λ. For example, when r(t)<λ(d, Δ), no faults are determined to exist. However, for example, when r(t)≥λ(d, Δ), a fault is determined to occur. In these examples, λ(d, Δ) is the threshold, which is based on the external noise d and the uncertainty Δ.

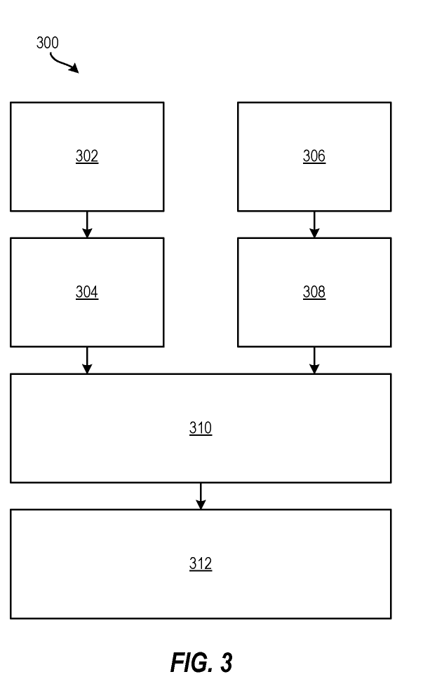

FIG. 3 depicts a flow diagram of a method 300 for fault diagnosis, according to aspects of the present disclosure. The method 300 can be performed by any suitable processing system or processing device, such as the fault diagnosis system 100 of FIG. 1, the fault diagnosis system 200 of FIG. 2, the processing system 700 of FIG. 7, or by any suitable combination thereof.

At block 302, a physical component module is emulated as a real system M(s) for the FTCA system 110. At block 304, the FTCA system 110 output y(t) is read. The output y(t) includes a fault component f(t) that is caused by a fault within the FTCA system 110. At block 306, the model observer engine 106 observes the FTCA system 110 and, at block 308, generates an estimated system output ŷ(t) of the FTCA system 110.

At block 310, the model observer engine 106 generates residual signals r(t) where r(t)=(y(t)+f(t))−ŷ(t). At block 312, the fault diagnosis engine 108 performs a fault diagnosis to determine whether a fault occurred within the FTCA system 110. If no fault is determined to have occurred, r(t) is zero and therefore f(t) is also zero. However, if a fault is determined to have occurred, f(t) is equal to r(t).

Additional processes also may be included, and it should be understood that the processes depicted in FIG. 3 represent illustrations and that other processes may be added or existing processes may be removed, modified, or rearranged without departing from the scope and spirit of the present disclosure.

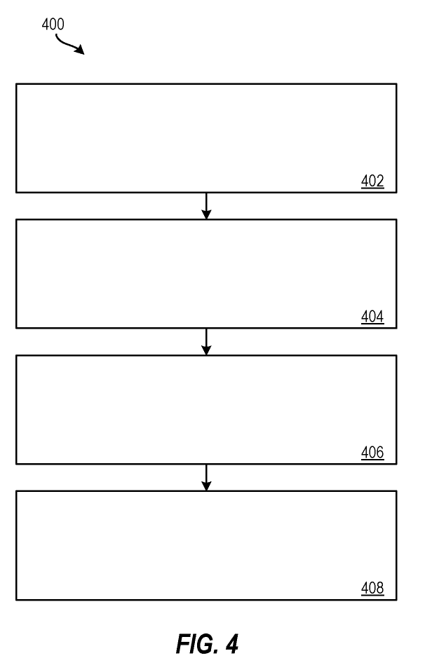

FIG. 4 depicts a flow diagram of a method 400 for fault diagnosis, according to aspects of the present disclosure. The method 400 can be performed by any suitable processing system or processing device, such as the fault diagnosis system 100 of FIG. 1, the fault diagnosis system 200 of FIG. 2, the processing system 700 of FIG. 7, or by any suitable combination thereof.

At block 402, the model observer engine 106 of the fault diagnosis system 100 receives a control variable (e.g., an expected input to the FTCA system 110). According to the example of FIG. 1, the control variable is designated u(t).

At block 404, the model observer engine 106 receives a measured variable (e.g., a measured output of the FTCA system 110). According to the example of FIG. 1, the measured variable is designated y(t).

At block 406, the model observer engine 106 calculates a residual based on the control variable and the measured variable. The model observer engine 106 generates an estimated system output of the FTCA system 110 using the control variable and the measured variable and uses the estimated system output to calculate the residual. According to the example of FIG. 1, the estimated system output of the FTCA system 110 is designated ŷ(t). The model observer engine 106 uses the estimated system output (e.g., ŷ(t)) to calculate the residual signal, designated r(t). The residual signal r(t) is equal to the sum of the measured variable and a fault component f(t) (caused by a fault in the FTCA system 110) minus the estimated system output. That is, r(t)=(y(t)+f(t))−ŷ(t).

At block 408, the fault diagnosis engine 108 performs a fault diagnosis to detect a fault in the FTCA system 110 based on the residual r(t). In an example, detecting a fault includes comparing the residual to a threshold. If the threshold is exceeded, a fault is determined to exist. In another example, detecting a fault includes time averaging the residual and comparing the time average to a threshold. If the threshold is exceeded, a fault is determined to exist).

Additional processes also may be included, and it should be understood that the processes depicted in FIG. 4 represent illustrations and that other processes may be added or existing processes may be removed, modified, or rearranged without departing from the scope and spirit of the present disclosure.

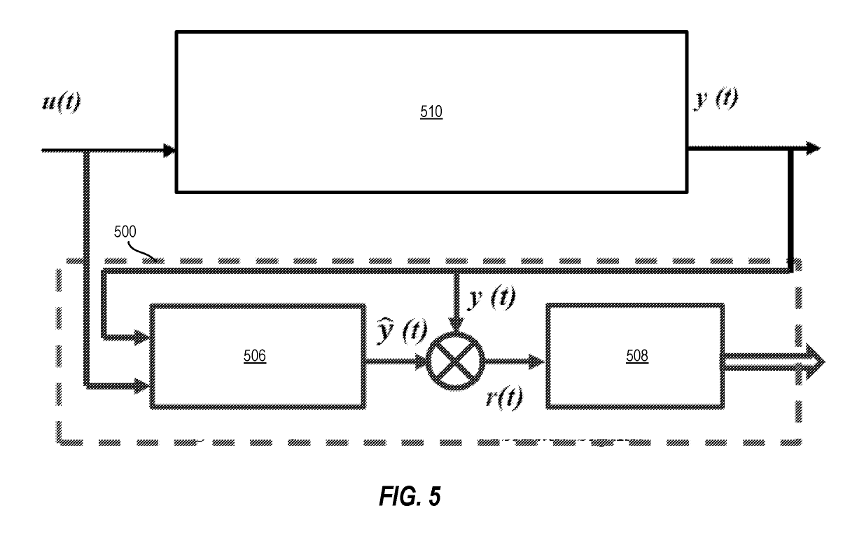

FIG. 5 depicts a block diagram of a fault detection implementation using a fault diagnosis system 500 to detect a fault within a system 510, according to aspects of the present disclosure. The various components, modules, engines, etc. described regarding FIG. 5 can be implemented as instructions stored on a computer-readable storage medium, as hardware modules, as special-purpose hardware (e.g., application specific hardware, application specific integrated circuits (ASICs), as embedded controllers, hardwired circuitry, etc.), or as some combination or combinations of these.

As depicted in FIG. 5, a physical system 510 is emulated as a real system M(s). In the example of FIG. 5, a pulse width modulated duty cycle serves as the input u(t) to the system 510, and the system 510 outputs a pressure signal y(t). The fault diagnosis system 500 includes math model \hat{M}(s) observer (e.g., the model observer engine 506) and a fault diagnosis engine 508.

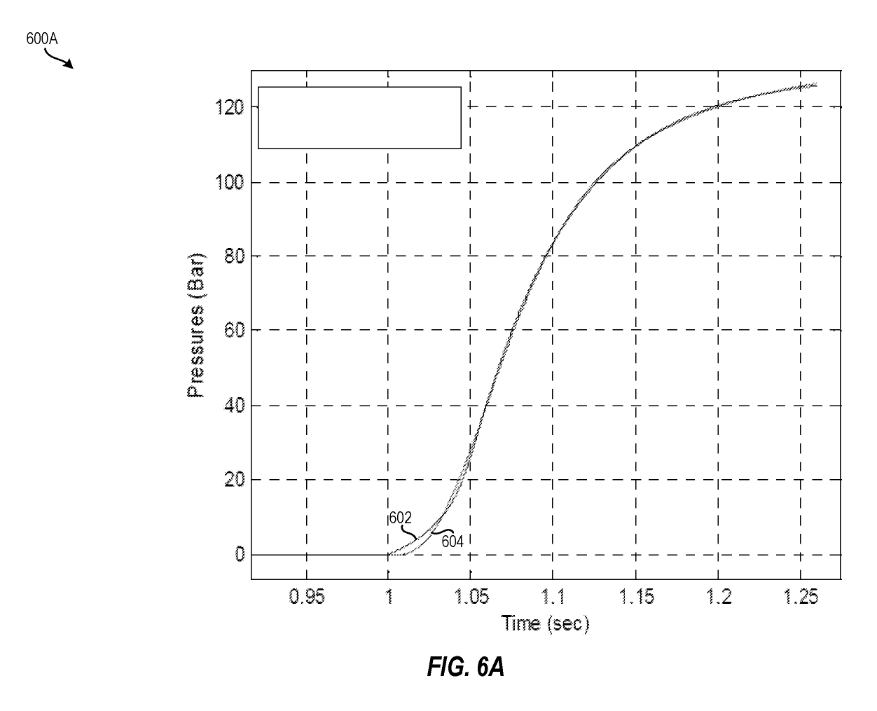

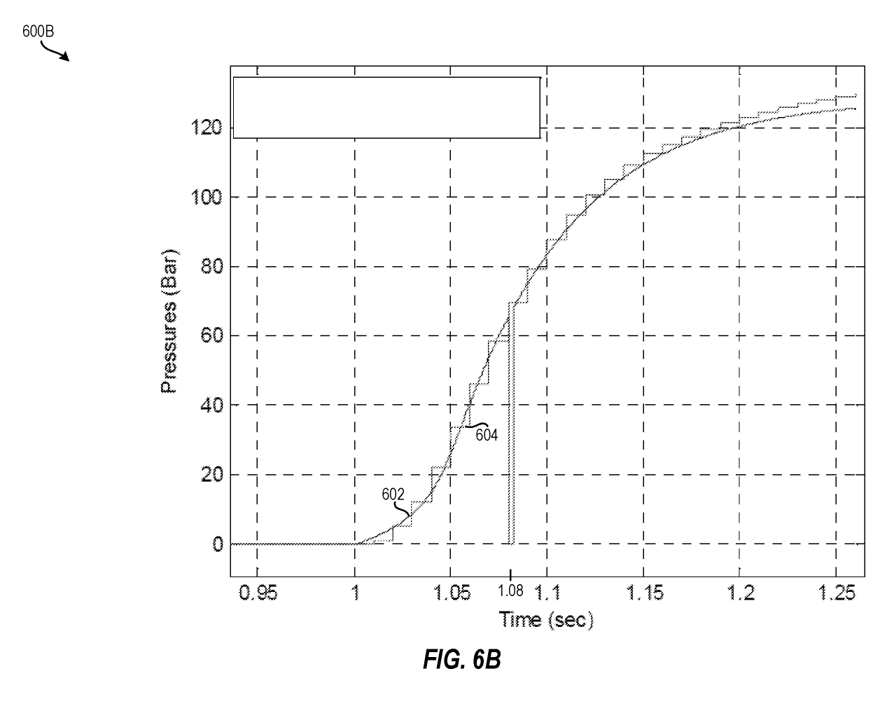

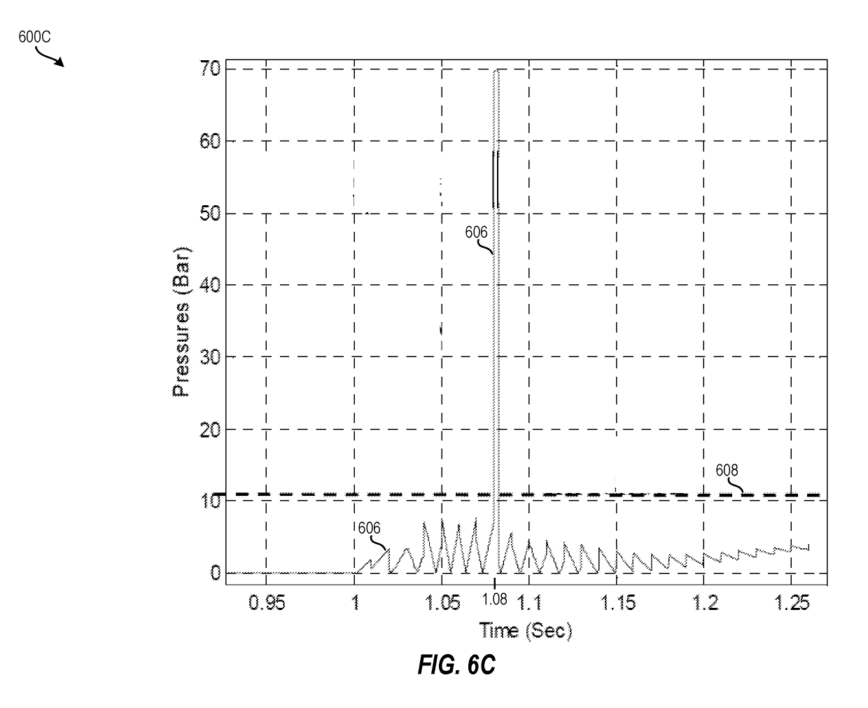

FIGS. 6A, 6B, and 6C depict graphs 600A, 600B, and 600C of aspects of the fault detection implementation of FIG. 5. Specifically, FIG. 6A depicts a graph 600A of the measured output 602 and modeled output 604 for pressure over time. In particular, the time responses of M(s) and \hat{M}(s) in the same control signal u(t) is shown. FIG. 6B depicts a graph 600B of the pressure response for pressure over time for the measured output 602 and the modeled output 604. For example, FIG. 6B depicts the time response when the pressure sensor “short” fault occurs in the time (approx.) 1.08 sec with sampling time 0.01 sec in the fault diagnosis system 500. FIG. 6C depicts the residual r(t) of pressure over time. In particular, FIG. 6C depicts the residual r(t) value 606, which is shown to exceed the threshold 608 at time 1.08 sec, and thus the fault diagnosis engine 508 determines a fault.

It is understood that the present disclosure is capable of being implemented in conjunction with any other type of computing environment now known or later developed. For example, FIG. 7 illustrates a block diagram of a processing system 700 for implementing the techniques described herein. In examples, processing system 700 has one or more central processing units (processors) 721a, 721b, 721c, etc. (collectively or generically referred to as processor(s) 721 and/or as processing device(s)). In aspects of the present disclosure, each processor 721 can include a reduced instruction set computer (RISC) microprocessor. Processors 721 are coupled to system memory (e.g., random access memory (RAM) 724) and various other components via a system bus 733. Read only memory (ROM) 722 is coupled to system bus 733 and can include a basic input/output system (BIOS), which controls certain basic functions of processing system 700.

Further illustrated are an input/output (I/O) adapter 727 and a network adapter 726 coupled to system bus 733. I/O adapter 727 can be a small computer system interface (SCSI) adapter that communicates with a hard disk 723 and/or other storage drive 725 or any other similar component. I/O adapter 727, hard disk 723, and storage device 725 are collectively referred to herein as mass storage 734. Operating system 740 for execution on processing system 700 can be stored in mass storage 734. A network adapter 726 interconnects system bus 733 with an outside network 736 enabling processing system 700 to communicate with other such systems.

A display (e.g., a display monitor) 735 is connected to system bus 733 by display adaptor 732, which can include a graphics adapter to improve the performance of graphics and general computation intensive applications and a video controller. In one aspect of the present disclosure, adapters 726, 727, and/or 732 can be connected to one or more I/O buses that are connected to system bus 733 via an intermediate bus bridge (not shown). Suitable I/O buses for connecting peripheral devices such as hard disk controllers, network adapters, and graphics adapters typically include common protocols, such as the Peripheral Component Interconnect (PCI). Additional input/output devices are shown as connected to system bus 733 via user interface adapter 728 and display adapter 732. A keyboard 729, mouse 730, and speaker 731 can be interconnected to system bus 733 via user interface adapter 728, which can include, for example, a Super I/O chip integrating multiple device adapters into a single integrated circuit.

In some aspects of the present disclosure, processing system 700 includes a graphics processing unit 737. Graphics processing unit 737 is a specialized electronic circuit designed to manipulate and alter memory to accelerate the creation of images in a frame buffer intended for output to a display. In general, graphics processing unit 737 is very efficient at manipulating computer graphics and image processing, and has a highly parallel structure that makes it more effective than general-purpose CPUs for algorithms where processing of large blocks of data is done in parallel.

Thus, as configured herein, processing system 700 includes processing capability in the form of processors 721, storage capability including system memory (e.g., RAM 724), and mass storage 734, input means such as keyboard 729 and mouse 730, and output capability including speaker 731 and display 735. In some aspects of the present disclosure, a portion of system memory (e.g., RAM 724) and mass storage 734 collectively store an operating system to coordinate the functions of the various components shown in processing system 700.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present techniques not be limited to the particular embodiments disclosed, but will include all embodiments falling within the scope of the application.

What is claimed is:

1. A computer-implemented method for fault diagnosis of a system, the method comprising:
receiving, by a processing device, a control variable for the system;
receiving, by the processing device, a measured variable for the system;
calculating, by the processing device, a residual based at least in part on the control variable and the measured variable; and
performing, by the processing device, a fault diagnosis to detect a fault in the system based at least in part on the residual.

2. The computer-implemented method of claim 1, wherein performing the fault diagnosis comprises determining whether the residual exceeds a threshold.

3. The computer-implemented method of claim 2, wherein the fault diagnosis indicates that a fault exists in the system when the residual exceeds the threshold.

4. The computer-implemented method of claim 2, wherein the fault diagnosis indicates that a fault does not exist in the system when the residual does not exceed the threshold.

5. The computer-implemented method of claim 1, wherein the measured variable is based at least in part on measuring an output of the system.

6. The computer-implemented method of claim 1, wherein the control variable is based at least in part on estimating an output of the system based at least in part on an input into the system.

7. The computer-implemented method of claim 1, wherein calculating the residual comprises subtracting the control variable from the measured variable.

8. The computer-implemented method of claim 1, wherein the fault is in an actuator in the system.

9. The computer-implemented method of claim 1, wherein the fault is in a sensor in the system.

10. A fault diagnosis system comprising:
a memory comprising computer readable instructions; and
a processing device for executing the computer readable instructions for performing a method for fault diagnosis of a system, the method comprising:
receiving, by the processing device, a control variable for the system;
receiving, by the processing device, a measured variable for the system;
calculating, by the processing device, a residual based at least in part on the control variable and the measured variable; and
performing, by the processing device, a fault diagnosis to detect a fault in the system based at least in part on the residual.

11. The fault diagnosis system of claim 10, wherein performing the fault diagnosis comprises determining whether the residual exceeds a threshold.

12. The fault diagnosis system of claim 11, wherein the fault diagnosis indicates that a fault exists in the system when the residual exceeds the threshold.

13. The fault diagnosis system of claim 11, wherein the fault diagnosis indicates that a fault does not exist in the system when the residual does not exceed the threshold.

14. The fault diagnosis system of claim 10, wherein the measured variable is based at least in part on measuring an output of the system.

15. The fault diagnosis system of claim 10, wherein the control variable is based at least in part on estimating an output of the system based at least in part on an input into the system.

16. The fault diagnosis system of claim 10, wherein calculating the residual comprises subtracting the control variable from the measured variable.

17. The fault diagnosis system of claim 10, wherein the fault is in an actuator in the system.

18. The fault diagnosis system of claim 10, wherein the fault is in a sensor in the system.

19. A computer program product comprising:
a computer readable storage medium having program instructions embodied therewith, the program instructions executable by a processing device to cause the processing device to perform a method for fault diagnosis of a system, the method comprising:
receiving, by the processing device, a control variable for the system;
receiving, by the processing device, a measured variable for the system;
calculating, by the processing device, a residual based at least in part on the control variable and the measured variable; and
performing, by the processing device, a fault diagnosis to detect a fault in the system based at least in part on the residual.

20. The computer program product of claim 19, wherein performing the fault diagnosis comprises determining whether the residual exceeds a threshold.
